(19) United States
(12) Patent Application Publication
(10) Pub. No.: US 2010/0224227 A1
(43) Pub. Date: Sep. 9, 2010

(54) Energy generating device and method

(75) Inventor: Stephen Lindsey, London (GB)

Correspondence Address: CHALKER FLORES, LLP, 2711 LBJ FRWY, Suite 1036, DALLAS, TX, 75234, US

(73) Assignee: TWENTYNINETY LIMITED, London (GB)

(21) Appl. No.: 11/913,310

(22) PCT Filed: May 4, 2006
(86) PCT No.: PCT/GB06/01608

§ 371 Date: May 28, 2008

(30) Foreign Application Priority Data
May 4, 2005 (GB) 0509083.2

(51) Int. Cl. H01L 31/042; H01L 31/04; H01L 31/02

(52) U.S. Cl. 136/244; 136/252; 257/E31.001; 257/E31.11

(57) ABSTRACT

A photovoltaic module is described, the module including at least one photovoltaic cell. The module also includes means for storing an identifier for the photovoltaic module, a sensor for sensing the value of at least one parameter indicative of the operation of the photovoltaic module and an electronic communication device for transmitting data comprising the value of the at least one parameter and the identifier for the photovoltaic module to a remote device. There is also described an electronic communication device for a photovoltaic module and an array of such photovoltaic modules, which may form an energy generation system. Methods of monitoring the operation of one or more photovoltaic modules as well as managing and communicating with the modules are also described.

The present invention relates to the field of energy generating devices and, in particular to the field of photovoltaic, or solar, cells and modules.

Photovoltaic cells convert light energy, in particular solar energy, into electrical energy. Cells may be arranged in an array as a photovoltaic module, and a plurality of photovoltaic modules may be arranged in a larger array, for example on the roof or walls of a building, to provide a network of photovoltaic modules providing energy for the building. Module arrays may be installed by technicians to an existing building or may be installed by builders or roofers as the building is constructed. To allow easy installation, the modules are often manufactured so that they simply click or slot together with minimal wiring required.

However, once installed, the array of modules is not easily accessible for maintenance or testing of each module and, to obtain the maximum performance from the solar module array, a trained technician is required to climb onto the roof or obtain access to the building structure to check the operation of each module. This process is costly and time-consuming and may require individual decoupling and rewiring of each module to check its operation.

According to one aspect, there is provided a photovoltaic module comprising:

at least one photovoltaic cell;

means for storing an identifier for the photovoltaic module;

a sensor for sensing the value of at least one parameter indicative of the operation of the photovoltaic module;

an electronic communication device for transmitting data comprising the value of the at least one parameter and the identifier for the photovoltaic module to a remote device.

Providing a photovoltaic module with a communication device to communicate the value of a parameter together with an identifier for the photovoltaic module to a control device may advantageously enable the detection of the operational state of individual photovoltaic modules in an array of modules without requiring each module to be inspected individually. In particular, by transmitting the data to a remote device, the operational state of the photovoltaic module may be determined and monitored remotely.

In one embodiment, the electronic communication device may comprise a radio frequency transmitter. Hence the data may be transmitted to the control device without requiring additional wiring in the installation of the photovoltaic modules.

Preferably, the electronic communication device comprises an RFID protocol transmitter, which may be termed an RFID tag or an RFID module.

In this embodiment, the identifier for the photovoltaic module may comprise the identifier of the RFID transmitter. Each photovoltaic module is preferably provided with a unique identifier.

In an alternative embodiment, the electronic communication device may comprise means for transmitting the data via a physical connection.

The physical connections may include a power wire through which the electrical energy generated by the photovoltaic module is output. Hence the system may take advantage of existing wiring to transmit the data.

Alternatively, the physical connection may include a wire separate to the power wire through which the electrical energy generated by the photovoltaic module is output. Hence an additional wiring system may be provided to transmit the data.

In a preferred embodiment, the sensor comprises means for sensing the voltage generated by the photovoltaic module. The sensitivity of the sensor may be less than around 1V. Preferably, the sensitivity of the sensor may be less than around 0.5V, preferably around 0.1V.

The sensor may be arranged to output a value indicative of one of a limited number of cell operating conditions, preferably no more than a total of 4 conditions (which may be transmitted as 2 bits in one embodiment).

The cell operating conditions may include inactive and active and optionally one or more approximate quality indications, preferably wherein the conditions comprise less than about 16 categories (4 bits). For example, the quality indications may indicate the voltage being generated by the photovoltaic module.

In a highly preferred embodiment, the at least one parameter comprises the voltage generated by the photovoltaic module, preferably having an accuracy of at least 4 bits, more preferably at least 8 bits.

Alternatively, or in addition, the at least one parameter may comprise at least one of the current generated by the photovoltaic module or the temperature of a portion of the photovoltaic module.

Preferably, the module further comprises means for storing the value of the at least one parameter indicative of the operation of the photovoltaic module.

In one embodiment, the photovoltaic module may comprise an array of photovoltaic cells. Hence the photovoltaic module may be made up of a plurality of cells, each arranged to generate energy. The cells may be connected in serial or in parallel or groups of cells may be connected in serial, the groups being connected together in parallel.

The at least one parameter may comprise a parameter indicative of the operation of the array of photovoltaic cells.

Alternatively, the at least one parameter may comprise a plurality of parameters, each parameter being indicative of the operation of at least one cell in the array of photovoltaic cells.

In one embodiment, the radio frequency transmitter may be arranged to transmit the data to a neighbouring photovoltaic module for onward transmission to the remote device. In this embodiment, the transmission range may be around l1 or less.

The module may further comprises means to interface with a further photovoltaic module to transmit the data comprising the at least one parameter to the further photovoltaic module.

In an alternative embodiment, the radio frequency transmitter may be arranged to transmit the data directly to the remote device, for example to a central receiver system, such as an aerial in the roof on which the photovoltaic module is installed.

For example, the radio frequency transmitter may have a transmission range of greater than around 2 m, preferably greater than around 8 m.

In one embodiment, the electronic communication device may be powered by electrical energy generated by the photovoltaic module. This may simplify the design of the photovoltaic module and reduce its cost, size and weight, since it would not be necessary to include an additional power, source in the photovoltaic module.

Alternatively, the photovoltaic module may further comprise a power supply for supplying power to the electronic communication device. This may allow the electronic communication device to operate even when the photovoltaic module is not generating energy, for example in the dark or before installation of the photovoltaic module. The power supply may comprise a battery or a capacitor.

The photovoltaic module may further include means to interface with a remote device having a web client interface. For example the photovoltaic module may be connected directly or indirectly to a server connected to the interne. Data from the photovoltaic module may be accessed by the owner of the module, or by third parties, via the web client interface. Alternatively, or in addition, the remote device may comprise any type of computer interface, for example a database. The apparatus may include means for issuing one or more database writing or updating commands, for example SQL (or related e.g. T-SQL) commands and/or means for writing into a memory table. Additionally or alternatively, the system may be managed using a protocol derived from network management, e.g. using the principles of an SNMP MIB management system.

According to a further aspect, there is provided an array of photovoltaic modules, each photovoltaic module comprising a module according to the aspect above or the aspect in combination with any of its preferred features.

In a preferred embodiment, each photovoltaic module in the array may comprise a sub-array of photovoltaic cells.

Preferably the identifiers for each of the photovoltaic modules in the array are mutually distinct. Hence data relating to one photovoltaic module may easily be distinguished from data relating to other photovoltaic modules in the array.

Preferably, the photovoltaic modules are connected by a physical connection. The physical connection may be used to transmit power generated by the photovoltaic modules or may be a connection separate to the power collection network.

In one embodiment, the electronic communication devices transmit the data over the physical connection. For example, the data may be transmitted as a modulated signal over the power transmission lines. Alternatively, the data may be transmitted over a separate physical connection.

In alternative embodiment, the electronic communication devices of the array of photovoltaic modules are connected in a mesh network. As described in more detail below, connecting the communication devices in a mesh network may allow the data to be collected by being passed from one communication device to another in a chain. Data gathered in this way from a number of communication devices may then be transferred to a central data collection system. This may reduce the transmission power required by each communication device and reduce the cost, size and power requirements of each device.

In one embodiment, for example in a mesh network set-up, each electronic communication device may transmit the value of the predetermined parameter and the identifier to a neighbouring electronic communication device for onward transmission to the remote device. In this way, the data may be passed along a chain of photovoltaic modules to the remote device or data collection unit.

Preferably, an electronic communication device of at least one photovoltaic module transmits the values of the predetermined parameter and the identifiers for a plurality of photovoltaic modules to a remote device.

According to a further aspect, there is provided an energy generation system comprising at least one photovoltaic module according to the aspect described above or the aspect in combination with any of its preferred features and a remote device for receiving data transmitted by the electronic communication device of the at least one photovoltaic module.

In one embodiment, the remote device may comprise a radio frequency receiver. Preferably, the remote device comprises an RFID protocol receiver.

In an alternative embodiment, the remote device may be connected to at least one photovoltaic module via a physical connection.

The remote device may comprise a hand-held receiver, for example a hand-held RFID protocol receiver device.

In a highly preferred embodiment, the remote device is arranged to communicate with a computer system. The remote device may be connected to the computer system via a network, such as the internet.

Alternatively, the remote device may comprise a computer system connected to a receiver, for example a computer terminal connected to an aerial. The computer system may be connected to the receiver via a network, such as the internet.

The computer system preferably processes data received from the electronic communication device and displays the processed data.

In a highly preferred embodiment, the computer system includes a web interface. This may allow the data to be accessed remotely, for example the data may be accessed securely using a user name and password.

According to a further aspect, there is provided an electronic communication device for a photovoltaic module comprising:

means for storing an identifier of the photovoltaic module;

means for sensing the value of at least one parameter indicative of the operation of the photovoltaic module;

an electronic communication device for transmitting data comprising the at least one parameter and the identifier for the photovoltaic module to a remote device;

means for coupling the electronic communication device to a photovoltaic module.

According to a further aspect, there is provided a method of monitoring the operation of at least one photovoltaic module, the method comprising:

receiving data comprising an identifier and a value of at least one parameter indicative of the operation of the photovoltaic module from the or each photovoltaic module;

determining the operating status of the or each photovoltaic module based on the received data;

generating an output indicating the operating status of one or more photovoltaic modules.

Determining the operating status preferably comprises analysing the value of the at least one parameter to determine one of a limited number of categories of cell operating conditions.

The cell operating conditions may include active, inactive and optionally one or more approximate quality indications.

In a preferred embodiment, an alert signal is generated if the received data indicates that one or more photovoltaic modules is not operating or is operating sub-optimally.

Preferably, analysing the received value comprises comparing the value received for the or each photovoltaic module to at least one other received value for a photovoltaic module and determining the operating status based on the comparison. Comparing values between photovoltaic modules may enable the system to eliminate the possibility that a particular photovoltaic module is not generating energy because of external factors, such as a lack of sunlight, rather than because of a fault in the photovoltaic module.

Generating the output may comprise generating an indication of the power generated by the or each photovoltaic module.

Alternatively or in addition, generating the output may comprise generating an indication of the power generated by a selected plurality of photovoltaic modules.

In a highly preferred embodiment, the method includes monitoring the output, over time to detect variations in the operating status of the or each photovoltaic module or of a selected plurality of photovoltaic modules. Changes over time of the output may indicate a failure or decrease in performance of a photovoltaic module. The output may be compared to previous equivalent outputs, for example an output at the same time of day or in the same weather conditions as the present output to determine any changes in performance of the photovoltaic module.

The output may be used to determine an expected lifetime for the photovoltaic module. For example, the expected time to failure for a particular type or batch of modules may be determined.

The data from each photovoltaic module may further be grouped into one of a plurality of groups of data based on the identifier of the photovoltaic module. Hence the data may be grouped according to the owner of the photovoltaic module or according to the position of the module in the installation etc.

In a highly preferred embodiment, the output may be displayed at a user interface. The output may be processed further before display as described in more detail below.

The output for a selected group of photovoltaic modules may be displayed at a user interface. For example, the output for all photovoltaic modules having a particular owner may be displayed.

In a preferred embodiment, the output may be displayed in graphical format, for example as a bar chart or graph of the energy generated over time.

According to a further aspect, there is provided a method of monitoring the operation of an array of photovoltaic modules, the method comprising:

receiving data comprising an identifier and a value of at least one parameter indicative of the operation of the array of photovoltaic modules from at least one photovoltaic module;

determining the operating status of the array of photovoltaic modules based on the received data;

generating an output indicative of the operating status of the array of photovoltaic modules.

In a preferred embodiment, receiving data comprises receiving an identifier and a value of at least one parameter for each photovoltaic module in the array of photovoltaic modules.

The method preferably further comprises changing the characteristics of circuitry connected to the output of the array in response to the output generated.

Changing the characteristics of circuitry connected to the output of the array may comprise tuning the power conversion system in response to the output generated. For example the inverter for the system may be tuned in response to the output to maximise the output power.

The method may further comprise changing the characteristics of circuitry connected to the output of the array based on stored output data.

The characteristics may further be changed based on expected output data generated using the stored output data. The stored output data may provide an indication of the most efficient configuration for the circuitry, for example output data generated under the same climatic conditions as those currently prevailing may be used to determine the optimum configuration for the circuitry.

In a preferred embodiment, the stored output data may comprise the power generated by the photovoltaic module over a day. Hence the optimum configuration at a particular time of day may be calculated using the stored output data.

According to a further embodiment, there is provided a method of managing an array of photovoltaic modules, the method comprising:

receiving data comprising an identifier and a value of at least one parameter indicative of the operation of the photovoltaic module from each photovoltaic module;

assigning each photovoltaic module to one of a plurality of categories of photovoltaic modules based on the identifier received;

storing the data for each photovoltaic module together with an identifier of the category for the photovoltaic module;

processing the data for each photovoltaic module based on the category assigned.

Preferably, processing the data comprises generating output data for the photovoltaic modules in a selected category of photovoltaic modules.

The output data may comprise an indicator of the power generated by the photovoltaic modules in a selected category of photovoltaic modules.

In one embodiment, the categories of photovoltaic modules may be defined based on the ownership of the photovoltaic modules. In this way, the information including the operating status of photovoltaic modules and the total power generated by photovoltaic modules belonging to a particular client account may be collated and transmitted to the module owner.

According to a further aspect, there is provided a method of managing an array of photovoltaic modules, the method comprising:

receiving data comprising an identifier and a value of at least one parameter indicative of the operation of the photovoltaic module from each photovoltaic module;

determining a category for the data based on the identifier;

generating payment information for each category of data.

In a preferred embodiment, the category for the data may be determined based on the ownership of the photovoltaic module. A list of identifiers of photovoltaic modules belonging to each owner may be stored and the owner of a photovoltaic module may be determined by comparing the identifier for data received to the list of identifiers. The payment information may be billing information or rebate information, for example the information may indicate how much of a discount the owner gets from his electricity bill by providing the energy supplied by the photovoltaic modules to the electricity grid.

According to a further aspect, there is provided method of determining the relative position of a photovoltaic module in an array of photovoltaic modules, the method comprising:

providing an electronic communication device associated with each of a plurality of photovoltaic modules in the array of photovoltaic modules;

storing an identifier at each electronic communication device;

transmitting the identifier from the electronic communication device to a central receiver device;

determining a relative location for each of the plurality of photovoltaic modules based on the transmission of the identifier.

Hence the relative positions of photovoltaic modules in an array of photovoltaic modules may be determined automatically, for example by a central remote device or by the photovoltaic modules themselves.

Preferably, the electronic communication device comprises a radio frequency transmitter. Further preferably, the electronic communication device comprises an RFID protocol transmitter.

In one embodiment, the relative location may be determined based on the strength of a signal transmitted by the electronic communication device.

In an alternative embodiment, the relative location may be determined based on a time of flight calculation of a signal transmitted by the electronic communication device.

Embodiments of the system and method described herein will now be described in more detail with reference to the Figures in which:

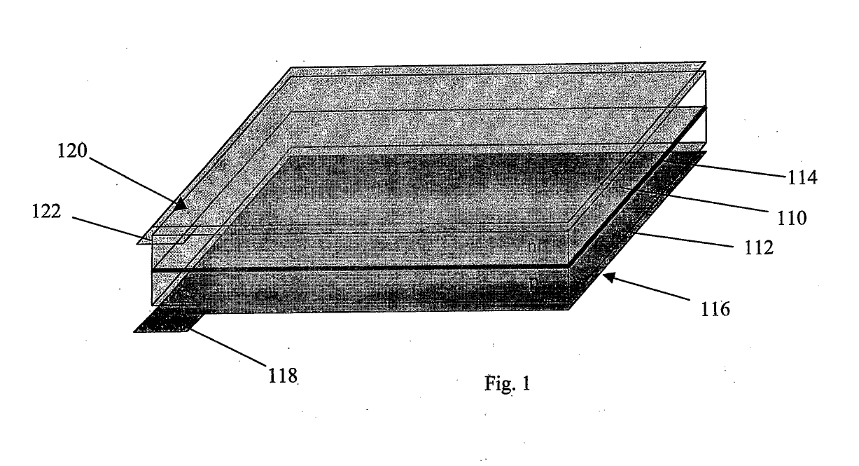

FIG. 1 is a schematic diagram of a prior art photovoltaic module;

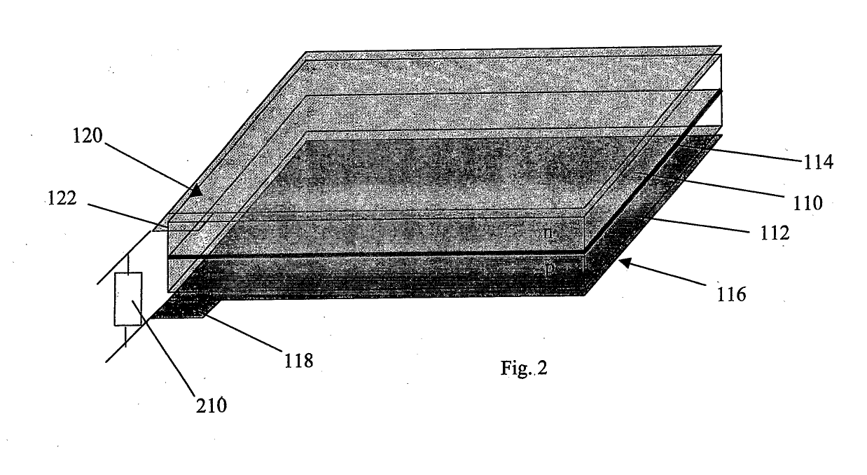

FIG. 2 is a schematic diagram of a photovoltaic module incorporating a communication device according to one embodiment;

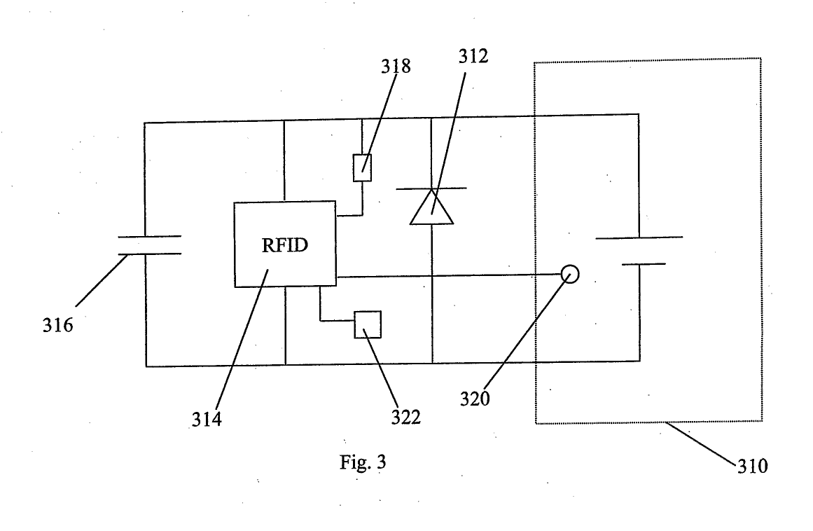

FIG. 3 illustrates schematically a photovoltaic module including an RFID protocol transmitter according to one embodiment;

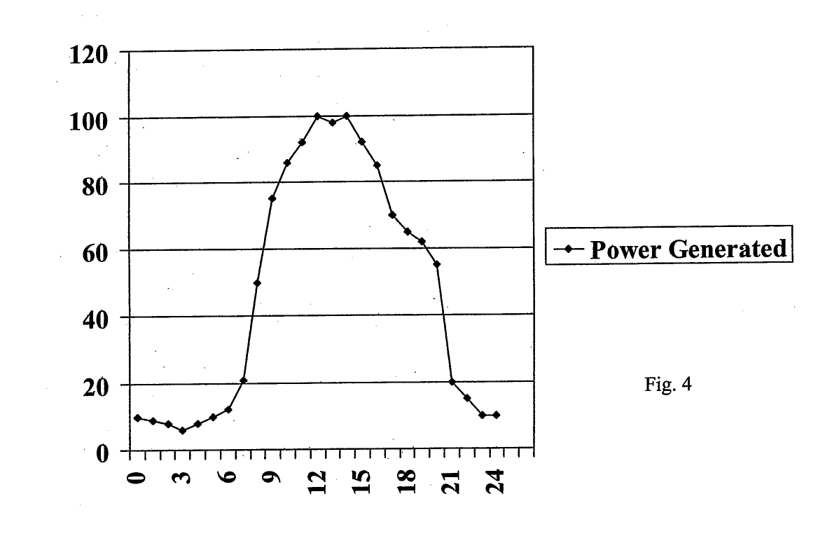

FIG. 4 is a schematic diagram of a sample output of a system according to one embodiment;

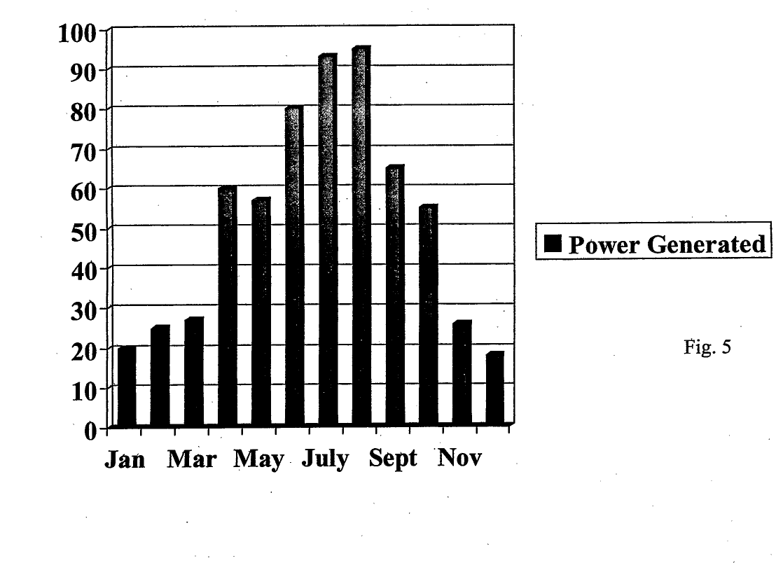

FIG. 5 is a schematic diagram of a further sample output of a system according to one embodiment;

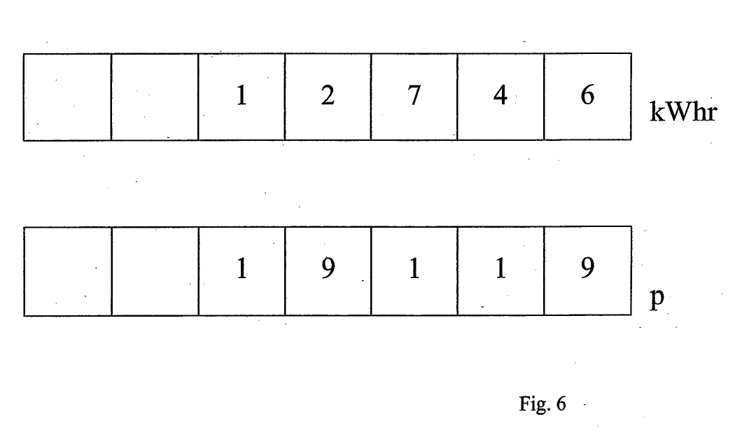

FIG. 6 is a schematic diagram of a further sample output of a system according to one embodiment;

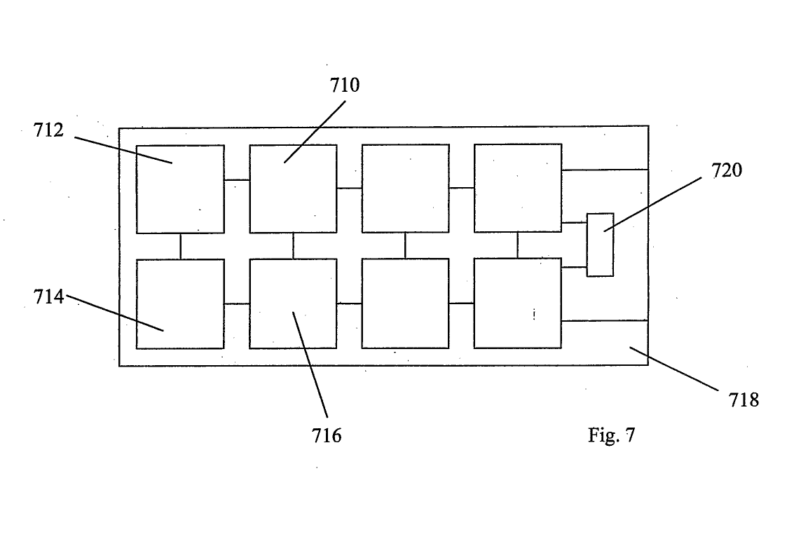

FIG. 7 is a schematic diagram of an array of photovoltaic modules according to one embodiment.

The structure of a simple prior art photovoltaic cell will now be described with reference to FIG. 1. A photovoltaic module may comprise a single photovoltaic cell or may comprise an array of photovoltaic cells. Photovoltaic cells comprise a number of layers. At the centre of a photovoltaic cell, an n-type semiconductor layer 110 is placed on top of a p-type semiconductor layer 112. The semiconductor layers typically comprise doped silicon layers, but may comprise other suitable semiconductor materials. The n-type layer may be doped with a material such as arsenic or phosphorous. The p-type layer may be doped with a material such as boron. Where the two layers join, a p-n junction is formed 114. The p-n junction 114 forms a diode, which allows electrons to flow from the p-type layer 110 to the n-type layer 112 on the application of a voltage in this direction, but which prevents current flow in the opposite direction.

The photovoltaic cell is also provided with a positive terminal 116 over the base of the module, which may be a continuous metallic layer, and a negative terminal 120 over the top surface of the module. Both the positive and the negative terminals 116, 120 include terminal connection points at one edge of the module 118, 122. Since the negative terminal 120 covers the top surface of the solar module, it must be formed in a way that does not block too much light from the cell, but which enables efficient collection of charge from the cell. In general, the negative terminal is formed by an electrical conductor in a grid pattern, which allows light through to the cell but which enables the collection of current from the cell.

The photovoltaic cell is usually also covered with a glass or other protective transparent cover (not illustrated in FIG. 1) to protect the cell during handling, installation, cleaning and in operation.

Arrays of photovoltaic cells or modules may be installed by slotting the connection points 118, 112 of one cell or module into those of an adjoining cell or module or by wiring an array of cells or modules together. Photovoltaic cells/modules may be installed on the roofs or walls of existing buildings or may be incorporated into structures of new buildings. For example, the cells may be incorporated into Building Integrated Renewable systems such as roofing tiles, panels or fascia boards or may be incorporated into photovoltaic modules for use in, for example conservatories and balcony fascias. Their simple construction and connection may enable the cells to be installed by builders or roofers with only minimal training.

One embodiment of a photovoltaic cell according to the present invention will now be described with reference to FIG. 2, which is a schematic illustration of one embodiment.

The photovoltaic cell of FIG. 2 contains all of the elements of the photovoltaic cell of FIG. 1 but, in addition, incorporates an electronic communication device 210. In this embodiment, the electronic communication device is a Radio-Frequency Identification (RFID) protocol transmitter arranged between the terminals of the photovoltaic cell. As will be clear to one skilled in the art, other communication devices may be used in conjunction with the system described herein. The RFID protocol transmitter may be referred to herein as an RFID tag or an RFID module.

The RFID module comprises an antenna for communicating with an interrogation device and an integrated circuit, including a data storage device for storing a code unique to the RFID module (at least for that installation of photovoltaic cells) and a processor. The RFID module may also comprise a transmitter for transmitting data, for example data relating to the photovoltaic cell, to an interrogation device. The RFID module may further comprise a receiver for receiving a signal from an RFID reader.

The transmitter and receiver include at least one antenna. They may be provided with a single antenna, or with two separate antennae preferably arranged to be polarised at 90° to minimise interference between the transmission and receipt signals.

A further data storage means may be provided internally or externally to the RFID module for receiving and storing data relating to the performance and operation of the photovoltaic cell. Alternatively, this data may be stored in the data storage device of the RFID module.

Integrated with or attached to the RFID module may be one or more sensors for sensing values of characteristics or predetermined parameters relating to the operation of the photovoltaic cell. For example a voltage measurement device may be provided for measuring the voltage across the terminals of the photovoltaic cell or a temperature sensor may be provided for measuring the temperature of at least a portion of the photovoltaic cell. (The temperature of the cell relates to the efficiency of the cell.)

One embodiment of the system described herein may be implemented using a passive RFID module, which does not contain its own power source. In this embodiment, the RFID module may communicate with an interrogation device by backscattering the radiation received from the interrogation device.

In an alternative embodiment, the tag may include a transmitter, which may be powered by collecting power from the interrogation signal or by an inductive power source, to transmit the data back to the interrogation device.

In a preferred embodiment, however, the transmitter incorporated into the tag may be provided with an independent power source. The power source may comprise power generated by the photovoltaic cell or may be provided by an additional power source, such as a battery, for example a watch-style battery, or a capacitor. Alternatively, the tag may be powered from the cell connections (when the cell is shaded).

Powering the tag using power generated by the photovoltaic cell may provide the advantage that a separate battery need not be provided to power the tag, reducing the cost and weight of the photovoltaic cell. However, in this embodiment, the tag would only operate when power was being generated by the photovoltaic cell. Hence the tag may not operate if the photovoltaic cell failed to operate and may not operate during transportation and storage of the photovoltaic cell, for example if the cell is stored in the dark. In an alternative embodiment, a single power source may be connected to operate a plurality of tags corresponding to a plurality of photovoltaic cells. For example, tags may be connected in parallel with a single external power source.

The photovoltaic cells and tags may be connected so that a resilient power supply may be provided for each tag. For example, power generated by each photovoltaic cell in a group of photovoltaic cells may be used by any one of a plurality of associated tags.

In one embodiment, the tag may be powered by the photovoltaic cell but a battery may be provided to provide backup power for the tag for use when the photovoltaic cell is not generating power, for example during storage and transportation of the modules or cells.

As described above, each photovoltaic cell may include its own individual transmitter. However, in a preferred embodiment, a plurality of photovoltaic cells is formed into an array, which may be termed a photovoltaic module and the module includes a single transmitter device. In this embodiment, data may be collected either relating to the operation of the module as a whole or the operation of individual cells that make up the module. FIG. 7 is a schematic diagram of a plurality of photovoltaic cells 710, 712, 714, 716 in the form of a photovoltaic module 718 including a single transmitter device 720.

In one embodiment, the range of the transmitter device or tag is preferably greater than around 10 m but, as will be clear to one skilled in the art, the range selected for the tag will depend on factors such as the distance over which the tag is required to transmit the data to the receiver. The voltage of the module, in a typical embodiment, is likely to be around 3 to 6 Volts and the accuracy with which the tag is expected to determine the voltage may be around 0.2V, although a more accurate sensor may be incorporated into the tag if necessary.

The tag and, optionally, the power supply, may be built into a photovoltaic module on manufacture or may be implemented as a separate device to allow retrofitting of the tag to existing photovoltaic modules (for example by plugging it in line using existing connections) or to allow fitting of the device on installation of photovoltaic modules. The device may be available as a simple board or chip to be incorporated into other devices.

The tag may incorporate or may be connected to sensors to gather information relating to the operation of the photovoltaic module. In particular, the tag may determine, the voltage generated by the photovoltaic module. Alternatively, or in addition, the tag may determine the current generated by the photovoltaic module and/or the temperature over at least part of the module.

In one embodiment, the tag may be arranged so that the parameters read allow a fault condition to be determined in either the photovoltaic module or in the bypass diode. Other fault conditions may also be deduced from the tag outputs, for example bad connections or bad wires in the array may be deduced e.g. from sending a test signal and/or by monitoring voltage and current under different conditions and thereby deducing load or connection resistance. The tag is preferably arranged to enable both open and closed circuit failures to be deduced in the diode and the photovoltaic module.

The values determined for the parameters measured may be instantaneous values or may be values averaged over a predetermined period of time. The sensors may provide a continuous reading of the value or the value may be determined periodically. For example, the voltage generated by the photovoltaic module may be determined and output by the sensor continuously or may be sampled periodically.

Sensors associated with the tag may also be used to determine other parameters, for example pressure sensors may be used to determine the pressure or force acting on the modules, for example due to wind action and/or turbulence over the photovoltaic modules. This information could be used both to determine the forces to which the modules are subjected and to assess the effect of these forces on the operation of the modules. This may be implemented using pressure transducers or strain gauges.

Contact or strain-based sensors may also be provided to determine the strength of the fixing of the photovoltaic module. This may be useful in checking that the module has not become lose. Other sensors may be provided to determine the clarity of the upper surface of the module. This may be used to determine if a module needs to be cleaned.

The tag may further include a processing device, which may be used to generate information from the data gathered by the sensors or stored in the memory. For example, voltage data gathered over a period of a day may be processed to determine the average volt'age generated in each hour and/or the maximum and minimum voltages generated.

The tag preferably includes a data storage device, such as a Random Access Memory (RAM), which stores an identifier for the tag, such as its RFID identifier, together with data collected by sensors associated with the tag, for example the voltage generated by the module, or data output by the processing device. The data storage device may store only the most recent values for each of the parameters measured or may store historical values of the parameters, for example the average voltage generated by the module each hour for the past 10 hours.

In a preferred embodiment, the tag may be connected to or incorporated into the photovoltaic module in such a way as to enable the photovoltaic module to be installed in a standard way without any additional wiring or configuration. This may enable the modified photovoltaic modules to be connected by installers trained to connect existing photovoltaic modules without requiring any additional training. In an alternative embodiment, the tag may require additional installation, for example wiring or configuration of the system, on installation of the photovoltaic module.

A schematic diagram of one embodiment of an RFID transmitter connected to a photovoltaic module is illustrated in FIG. 3. The photovoltaic module 310, which may comprise one or more photovoltaic cells, is connected in a standard way to a bypass diode 312, which protects the photovoltaic module from harmful currents, particularly when the photovoltaic module is not generating energy. The photovoltaic module and diode are connected to an RFID transmitter 314. The RFID transmitter 314 may include a processor, a memory for storing an identifier and data collected by the sensors, and one or more aerials for transmitting and receiving information. As described above, a power source 316 may further be provided for the RFID transmitter 314. Sensors may also be provided to determine the operating status of the photovoltaic module. For example a voltage sensor 318 may be provided to determine the voltage generated by the photovoltaic module and a temperature sensor 320 may be provided to determine the temperature of a portion of the photovoltaic module. Further sensors, such as pressure sensors 322, or current sensors may also be provided.

Once the photovoltaic modules have been installed, the location of each RFID identifier may be determined. This may be done by scanning each area of the installation with an RFID reader to obtain the identifier of each RFID module, which may be used to determine the relative or absolute position of each tag, and hence each photovoltaic module. The configuration of the photovoltaic modules may be stored at a reader and/or in a central control system and data collected after installation of the system may be correlated with the stored location of each module.

In an alternative embodiment, the location of each photovoltaic module may be noted as the system is installed, either manually or with the use of an RFID or other reader.

Alternatively, mesh networking of the tags, as described in more detail below, may be used to derive at least a rough location of the tags, for example from using number of hops or time of flight style methods.

Alternatively, randomly shading an array may allow the location of individual modules to be derived. For example, moving a shading panel over an array from location to location may allow the installer to determine that modules are adjoining. If the modules are shaded in order, data may be collected to gather the identifiers of adjacent modules.

In a further embodiment, a method may be used by which the tags can determine their own position, for example by assessing the signal strength of transmissions from their neighbours. Alternatively, signal strength from one or more remote points or time of flight methods may be used to determine position by either the tag or a receiver. The modules may include position determining circuitry, which may range from a simple daisy-chain or other addressing system which enables position in an array to be determined through hard-wired connections up to e.g. a GPS-type system, which may operate on existing GPS satellites or a localised set of signalling points.

Data collected by and stored in the tag may be transmitted to a central diagnostic workstation or data collection unit in a number of different ways, some of which are described below. The data may be transmitted via an existing connection, for example via the wires down which the power generated by the photovoltaic modules is transmitted. In this case, the data transmitted by the tag may be transmitted as a modulated signal over the power transmitted down the wires. This provides the advantage that the wires are already in place and offer good connections. However, in this embodiment, data may only be transmitted by the tag after the tag is installed and not, for example, during manufacture or storage of the photovoltaic module.

In an alternative embodiment, a secondary diagnostic circuit may be wired on installation of the photovoltaic modules, in addition to the power circuit. The secondary diagnostic circuit may be used to transmit diagnostic information from the photovoltaic modules to a central data collection system.

Alternatively, the information may be transmitted by electromagnetic radiation, preferably by radio wave, back to a central system. In a preferred embodiment, each photovoltaic module may comprise an RFID module for transmitting diagnostic information relating to the operation of the photovoltaic module. The RFID modules may each transmit data directly to a single aerial connected to a central data collection system, for example a fixed aerial may be positioned in the roof of a building or within the supporting structure. The aerial may be in the form of a single aerial, a foil or wire attached to the inside of the roof or an external aerial or receiving box. The aerial may be connected to the central data collection system in any conventional manner, for example by direct wiring or by re-transmitting the data using radio or other technology. The central data collection system may comprise a fixed point, such as a central computer, or a moveable system, for example a hand-held RFID reader. Alternatively, groups of RFID modules may transmit data over a shorter distance to a group receiver, which may then forward the signal to a central system, for example over a wired network.

In an alternative embodiment, the RFID modules may be connected in a mesh network, wherein each RFID module transmits data to a neighbouring RFID module so that the data from a group of RFID modules is passed between RFID modules and transferred over the mesh network to a central data collection system, or to one or more receiving boxes which store and forward the data to a central system.

Receiving boxes, whether in a mesh system or otherwise, may communicate with a central system via a mobile telephone or modem that allows connection to a static telephone line or via a wireless card to allow direct communication with a Wi-Fi or other network.

In one implementation of a mesh system, each tag may require only enough transmission power to communicate with its nearest neighbour. This would reduce the cost of each transmitter and would provide robust data transfer at lower RF powers whilst being able to serve a large array of devices. Such a system may also imply fewer tag readers.

Any receiving device, such as those described herein may communicate with a central system, for example via a mobile telephone or modern that allows connection to a static telephone line (which term is intended to encompass any analogue or digital connection which permits data transmission, including ISDN, xDSL, Ethernet, optical) or via a wireless card to allow direct communication with a Wi-Fi or other network.

As will be clear to one skilled in the art, various protocols and receiving methods could be used to allow multiple tags to be interrogated.

The central data collection and/or analysis system could be a wired-in system with an output panel, a hand-held diagnostic reader, a production-line or conveyor-based system in a factory a computer-based system, a power meter, or any other appropriate system.

Once it has been received at the central data collection system, the data may be accessed directly via an interface at the system. The data may be analysed and stored at the central system, which may also enable the data to be accessed and downloaded to an auxiliary device, for example a hand-held device operated by a service engineer. Alternatively, the central data collection system may transmit the data over a network, for example over the internet, to a remote control centre for storage and analysis.

The information obtained from the array of photovoltaic modules may be used in a number of different ways.

The data obtained may be used to track the photovoltaic module throughout its lifecycle. During manufacture, the module could be tracked within the factory. In particular, quality control of photovoltaic modules could be implemented by testing each photovoltaic module, or a sample of modules, under a reference light source. The voltage generated by each photovoltaic module could then be determined using the communication device described herein and the generated voltages measured could automatically be associated with particular photovoltaic modules using the unique identifier transmitted with the data. Hence the effectiveness of each module could be assessed. Photovoltaic modules are complex and improved quality control may reduce returns, boost customer and installer confidence and reduce costs.

The identifier could also be used to track the location of each photovoltaic module within the factory. Similarly, the location of each photovoltaic module could be tracked during storage and distribution of the photovoltaic modules. This may allow suppliers and customers to determine the location of each order in an inventory tracking system and may also enable the factory of origin of each photovoltaic module to be determined.

The information relating to the location of each photovoltaic module throughout its manufacture and logistics lifecycle may also enable analysis of the cause of faults in the photovoltaic modules. For example, if a batch of photovoltaic modules fails after installation, it may be possible to determine the factory of origin of the photovoltaic modules as well as details of the storage and transportation of the photovoltaic modules. This may enable the manufacturer to determine whether a batch of photovoltaic modules was incorrectly stored at a particular warehouse or was handled in a way likely to cause failure of the devices.

Further, if an inventory tracking system is used to track modules at all stages from the manufacturer to various distributors to retailers, installers and to the site, any damage or performance drops could be located within the supply chain.

It is noted that, in order for the communication device associated with the photovoltaic module to transmit data and its identifier throughout the lifecycle of the product, it may be advantageous to provide the device with an independent power source, since the photovoltaic module itself will not be generating power throughout the lifecycle, for example during storage and transportation of the module. Alternatively, a transparent packing material could be used to enable at least some photovoltaic modules to generate enough power to operate the communication device even when packed.

If tracking is not provided throughout the lifecycle of the photovoltaic module, however, it is noted that it may still be possible to determine the factory of origin of each installed photovoltaic module by correlating the identifier stored by the communication device with the identifiers of photovoltaic modules noted during manufacture.

After installation, the identifier and the data transmitted by the communication device may be used for a wide variety of purposes. In one embodiment, the data may be used for diagnostic purposes. The communication device preferably transmits an indication of the voltage generated by the photovoltaic module together with the module identifier. The voltage data may be used to determine the state of operation of the photovoltaic module, for example the data may be used to determine whether a photovoltaic module has failed or to detect a drop in the performance of the photovoltaic module. Data available on a unit by unit basis (without need for direct connection to individual units) may aid in performance management and reduce maintenance costs.

For monitoring the performance of the photovoltaic module, it is preferable to monitor the voltage generated by the module, since measuring this parameter has a minimal impact on the operation of the photovoltaic module whilst allowing a wide range of functions of the photovoltaic module to be diagnosed. In an alternative embodiment, however, the current generated by the photovoltaic module or the temperature of part of the photovoltaic module may be measured.

Monitoring photovoltaic modules to determine failure or a decrease in performance of the modules may be useful in determining an expected lifetime for the modules. The information obtained may be used, for example, to create warranty schemes and/or lease, maintenance and service contracts for the photovoltaic modules. The information may also address payback economics issues in relation to photovoltaic modules and open the door to long term service contracts with utilities

Any change in the average lifetime of a module may also be used to determine faults in a batch of photovoltaic modules or in modules manufactured by a particular manufacturer. This may allow users of the modules to predict when other modules may fail. For example, if a number of photovoltaic modules from a particular batch have failed, it may be expected that other photovoltaic modules in the same batch may fail soon. These photovoltaic modules may then be scheduled for maintenance or replacement before they fail.

Changes in the average lifetime of a photovoltaic module may also enable manufacturers to determine the effects of changes in manufacturing techniques. For example, if a new adhesive is used within the photovoltaic module, the time to failure of the photovoltaic modules may be monitored to determine whether use of the new adhesive increased or decreased the average life of the modules.

Monitoring the performance of an installation of photovoltaic modules may also enable an installer or user to determine the effectiveness of the installation and any wiring associated with the installation. If the photovoltaic modules are not generating as much power as expected or if voltage is being lost from the modules, the installation may be checked to determine whether the performance of the system can be improved by correcting any errors in the installation. Since the voltage is measured for each photovoltaic module, any problems in the installation may be pinpointed to a particular module or section of modules. The data could also be used to determine under-performing areas of the installation, for example due to shading by other buildings or trees.

The installation may be altered to increase its effectiveness based on the data collected. For example, if one module is regularly shaded by a tree or chimney etc, and this is decreasing the performance of the entire string of modules, the installation could be changed (e.g. re-wired) to take this into account or the shading could be removed (e.g. by trimming a tree). Such analysis could also affect future installation guidelines.

The data transmitted by the communication devices may be used to determine the power generated by the installation or a section of the installation, such as an individual module, over a period of time. For example, the power generated each hour or each day may be transmitted to a consumer on whose roof the photovoltaic modules are installed. This may enable the consumer to monitor how much power the modules are generating, for example over a day or a month. The data may be presented to the consumer via a user interface, for example over a network such as the internet, in the form of numerical data or graphs of power generation. The form of the data presented to the user is preferably configurable by the user via the user interface. The data relating to the power generated by the photovoltaic modules may be converted into a monetary amount if the consumer received payment for the power generated.

Data may also be transmitted to a central database, for example at a utility company. Data may be analysed and presented to an interested party, such as the user or utility company in a wide variety of ways, as mentioned above. The power output could be displayed as a simple bar graph of other graphical display or shaded picture or could show power over time or the power of each individual module. The display could be in the form of a numerical display or as a meter-style reading. The output could be distributed over a network using a number of protocols so that the data could be picked up by a user with a computer either locally or remotely over a network or via another network such as a mobile telephone network (e.g. by text message).

In an installation owned jointly by a number of consumers, for example an installation on a block of flats owned by a number of flat owners or an office block shared by a number of companies, different photovoltaic modules may be assigned to different consumers. This may allow the billing to be distributed to individual users without having to wire each set of cells with individual meters.

The data relating to the power generated by each module may also be transmitted to the appropriate consumer based on the identifier transmitted with the data. For example, a consumer may receive data relating only to their assigned photovoltaic modules.

Data relating to the power generated by each module or group of modules may also be transmitted to a utility company so that each consumer can be reimbursed appropriately for their contribution to the power generation.

Examples of how data output for each photovoltaic module or a group of photovoltaic modules may be presented are provided in FIGS. 4 to 6. FIG. 4 is an example line graph illustrating the power output by a photovoltaic module over a day. As can be seen quickly from the line graph, the power output varies throughout the day, reaching a maximum during the sunniest periods of the day. FIG. 5 illustrates the power generated by a photovoltaic module over a year in the form of a bar graph. Similarly, it can be seen that the power output increases during the months with the greatest amount of sunshine. FIG. 6 is an illustration of a further embodiment output format for the data produced by the photovoltaic modules. The data in FIG. 6 is illustrated in the format of a digital meter reading, in which the total amount of power is illustrated together with amount of money generated from the power, for example by selling the power to the national grid. The meter reading may be provided to a user via a computer interface, for example over the internet, or via a physical meter.

It will be clear to one skilled in the art that the data received from the photovoltaic modules may be output in a large variety of different formats and the examples provided above are not intended to be limiting in any way.

Since any fault data transmitted by the photovoltaic modules will also have an associated identifier, fault warnings may also be transmitted to the consumer who owns the faulty module. Hence the appropriate consumer may be advised of the fault and may be responsible for correcting the faulty module.

Enabling the power generated by each photovoltaic module to be monitored and recorded may allow the sale or leasing of individual modules or groups of modules in an installation. For example, investors may buy rights to a particular module or group of modules in a larger commercial installation and, in return for maintaining and servicing their modules, the investors may receive the revenue due to the power generated by those modules in the installation. Ownership of the modules in the installation could be traded and transferred without disturbing the installation itself and the installation could be located remotely from the investors, for example in a remote sunny location. The amount of power generated could be monitored using an internet-style tracker similar to a stock market tracker or by other means.

A further use of the data collected from each photovoltaic module may be in weather monitoring and analysis. The power generated by the modules may vary depending on factors such as the cloud coverage over the installation. Data collected by different installations in a particular area, for example a number of installations across a town, may be collected and used to determine an accurate map of the current weather conditions across the area at a high level of granularity including, for example hours of sunlight, sunlight intensity, cloud cover etc. The data may be used to provide information on, for example, how sunny it is now in a specified area of the town rather than over a wider area. The movement of clouds and/or rain showers could also be tracked across an area, since a large cloud would sequentially shade installations.

In a further embodiment, the data gathered from the cells could be used to tune the efficiency of the array and of the inverters.

In general solar tiles or modules are connected together in series to form a string and then multiple strings are connected in parallel to form an array. For each string there will be an operating condition which gives maximum power output (at the inverter), and some inverters vary their internal resistance to maximise the power output. There is also the issue of matching the outputs of the individual strings and in many cases multiple inverters or multi-string inverters are used. There are many ways in which information could be gathered from the strings and their connections. Some of the intelligent or tracking inverters intermittently change their internal resistance and then compare the power output before and after to decide whether to stay at the new value.

The information from the system described herein could be used to actively tune the power conversion system. This could be reactive in that the information may be used in real time to assess the best operating point for the inverters and the string connections. Alternatively data built up from historical data (power against time of day, shading patterns etc.) could be used to pro-actively change the inverter or other electronics characteristics. In this way the extra data available could be used to maximise the power conversion of the array.

Further to this, if multiple inverters are used in a large array, one alternative is to use the proposed diagnostic chip to monitor the inverter characteristics in addition to or instead of monitoring the modules.

Alternatively or in addition, the output of an array of photovoltaic modules may be optimised by changing the configuration of the connections between photovoltaic modules or photovoltaic cells. For example, circuitry may be changed so that cells connected in series are reconnected in parallel to maximise the output of the cells.

It will be clear to one skilled in the art that the data obtained using the systems and methods described herein may be used for a wide variety of diagnostic and data-gathering functions and the examples set out above are not intended to be limiting in any way.

1. An apparatus comprising a photovoltaic module, the module comprising:
at least one photovoltaic cell;
a storage device for storing an identifier for the photovoltaic module;
a sensor for sensing the value of at least one parameter indicative of the operation of the photovoltaic module; and
an electronic communication device for transmitting data comprising the value of the at least one parameter and the identifier for the photovoltaic module to a remote device.

2. The apparatus according to claim 1 wherein the electronic communication device comprises a radio frequency transmitter.

3-4. (canceled)

5. The apparatus according to claim 1 wherein the electronic communication device comprises means for transmitting the data via a physical connection, including a power wire through which the electrical energy generated by the photovoltaic module is output.

6-7. (canceled)

8. The apparatus according to claim 1 wherein the sensor comprises means for sensing the output voltage of the photovoltaic cell.

9. The apparatus according to claim 8 wherein the sensor is arranged to output a value indicative of one of a limited number of cell operating conditions.

10-11. (canceled)

12. The apparatus according to claim 1 wherein the at least one parameter comprises at least one of the current generated by the photovoltaic module or the temperature of a portion of the photovoltaic module.

13. (canceled)

14. The apparatus according to claim 1 wherein the module comprises an array of photovoltaic cells.

15-17. (canceled)

18. The apparatus according to claim 1 further comprising means to interface with a further photovoltaic module to transmit the data comprising the at least one parameter to the further photovoltaic module.

19. The apparatus according to claim 2 wherein the radio frequency transmitter is arranged to transmit the data directly to the remote device.

20-30. (canceled)

31. The apparatus according to claim 1 wherein the photovoltaic module further comprises a connector for connecting an array of photovoltaic modules connected in a mesh network.

32-33. (canceled)

34. The apparatus according to claim 1 further comprising a remote device for receiving the data transmitted by the electronic communication device.

35. The apparatus according to claim 34 wherein the remote device comprises a radio frequency receiver.

36-40. (canceled)

41. The apparatus according to claim 34 wherein the remote device is arranged to communicate with a computer system and the computer system processes data received from the electronic communication device and displays the processed data.

42. (canceled)

43. An electronic communication device for a photovoltaic module comprising:
means for storing an identifier of the photovoltaic module;
means for sensing the value of at least one parameter indicative of the operation of the photovoltaic module;
an electronic communication device for transmitting data comprising the at least one parameter and the identifier for the photovoltaic module to a remote device; and
means for coupling the electronic communication device to a photovoltaic module.

44. A method of monitoring the operation of at least one photovoltaic module, the method comprising:
receiving data comprising an identifier and a value of at least one parameter indicative of the operation of the photovoltaic module from the or each photovoltaic module;
determining the operating status of the or each photovoltaic module based on the received data; and
generating an output indicating the operating status of one or more photovoltaic modules.

45. The method according to claim 44 wherein determining the operating status comprises analysing the value of the at least one parameter to determine one of a limited number of categories of cell operating conditions.

46. (canceled)

47. The method according to claim 44 wherein an alert signal is generated if the received data indicates that one or more photovoltaic modules is not operating or is operating sub-optimally.

48. The method according to claim 44 wherein determining the operating status comprises comparing the value received for the or each photovoltaic module to at least one other value received for a photovoltaic module and determining the operating status based on the comparison.

49. The method according to claim 44 wherein generating the output comprises generating an indication of the power generated by the or each photovoltaic module.

50-85. (canceled)

86. The apparatus according to claim 1 further comprising a device for determining a measure of the position of the photovoltaic module and wherein the electronic communication device further transmits data based on the measure of position to the remote device.
